(19) United States
(12) Patent Application Publication
(10) Pub. No.: US 2026/0022447 A1
(43) Pub. Date: Jan. 22, 2026

(54) MASK ASSEMBLY AND METHOD OF MANUFACTURING THE SAME

(71) Applicant: Samsung Display Co., Ltd., Yongin-si (KR)

(72) Inventor: DUCKJUNG LEE, Yongin-si (KR)

(21) Appl. No.: 19/201,628

(22) Filed: May 7, 2025

(30) Foreign Application Priority Data
Jul. 19, 2024 (KR) 10-2024-0095901

(51) Int. Cl. C23C 14/04; H10K 59/12; H10K 71/16

(52) U.S. Cl. CPC C23C 14/042; H10K 59/1201; H10K 71/166

(57) ABSTRACT

A mask assembly includes a mask support part having a plurality of cell openings, a mask on the mask support part, and having a plurality of cell regions overlapping the plurality of cell openings and a peripheral region surrounding the plurality of cell regions, and a tension part under the mask support part and overlapping the peripheral region. One side of the tension part and an other side of the tension part, which is opposite to the one side of the tension part, are fixed to the mask support part.

### CROSS-REFERENCE TO RELATED APPLICATIONS

This application claims priority to and the benefit of Korean Patent Application No. 10-2024-0095901, filed on Jul. 19, 2024, in the Korean Intellectual Property Office, the entire disclosure of which is incorporated by reference herein.

### BACKGROUND

The present disclosure herein relates to a mask assembly and a method of manufacturing the same, and more particularly, to a mask assembly with improved reliability and a method of manufacturing the same.

Display panels include a plurality of pixels. The pixels each include a drive element such as a transistor and a display element such as an organic light-emitting diode (OLED). The display element may be formed by stacking an electrode and a light-emitting pattern on a substrate.

A mask in which a hole is defined is used to perform patterning such that the light-emitting pattern is formed in a predetermined region. The light-emitting pattern may be formed in a region exposed by the hole of the mask. A shape of the light-emitting pattern may be controlled by a shape of the hole. Because repeated use of a production facility is required for manufacturing a great quantity of display panels, research may be needed so as to provide production facilities with improved reliability.

### SUMMARY

The present disclosure provides a mask and a mask support, which are included in a mask assembly, to be adhered to a target substrate without sagging due to a load.

One or more embodiments of the present disclosure provide a mask assembly including a mask support part having a plurality of cell openings, a mask on the mask support part, and including a plurality of cell regions overlapping the plurality of cell openings and a peripheral region surrounding the plurality of cell regions, and a tension part under the mask support part and overlapping the peripheral region, wherein one side of the tension part and an other side of the tension part, which is opposite to the one side of the tension part, are fixed to the mask support part.

In one or more embodiments of the present disclosure, a method of manufacturing a mask assembly includes forming a preliminary mask frame having conductivity, forming a preliminary mask on the preliminary mask frame, forming a mask by forming a plurality of holes passing through the preliminary mask, forming a mask frame by forming a plurality of cell openings in the preliminary mask frame, and fixing, to the mask frame, a tension part which does not overlap the plurality of cell openings on a plane.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles and scope of the present disclosure. In the drawings:

FIG. 1 is a cross-sectional view of a deposition apparatus according to one or more embodiments;

FIG. 2 is a plan view of a mask assembly according to one or more embodiments;

FIG. 3A is a cross-sectional view of a mask assembly taken along the line I-I′ of FIG. 2;

FIG. 3B is a cross-sectional view of a mask assembly taken along the line II-II′ of FIG. 2;

FIG. 4 is a plan view of a mask assembly according to one or more embodiments;

FIG. 5 is a plan view of a mask assembly according to one or more embodiments;

FIG. 6 is a plan view of a display panel manufactured using the mask assembly illustrated in FIG. 2;

FIG. 7 illustrates an example cross sectional view of one pixel illustrated in FIG. 6;

FIG. 8 illustrates a deposition process illustrated in FIG. 1;

FIGS. 9A-9E are cross-sectional views illustrating some steps of a method of manufacturing a mask assembly according to one or more embodiments; and

FIGS. 10A-10C are cross-sectional views illustrating some steps of a method of manufacturing a mask assembly according to one or more embodiments.

### DETAILED DESCRIPTION

The present disclosure may be implemented in various modifications and have various forms, and specific embodiments are illustrated in the drawings and described in detail in the text. It is to be understood, however, that the present disclosure is not intended to be limited to the particular forms disclosed, but on the contrary, is intended to cover all modifications, equivalents, and alternatives falling within the spirit and scope of the present disclosure.

In this specification, it will be understood that when an element (or a region, a layer, a portion, and/or the like) is referred to as being “on”, “connected to” or “coupled to” another element, it can be directly disposed on/connected to/coupled to the other element or layer or intervening elements may be disposed therebetween.

Like reference numerals or symbols refer to like elements throughout. Also, in the drawings, the thicknesses, ratios, and dimensions of the elements are exaggerated for effective description of the technical contents.

The term “and/or” includes all of one or more combinations that can be defined by related elements.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the spirit and scope of the present disclosure. The singular forms include the plural forms as well, unless the context clearly indicates otherwise.

Also, terms of “below”, “on lower side”, “above”, “on upper side”, and/or the like may be used to describe the relationships of the elements illustrated in the drawings. These terms have relative concepts and are described on the basis of the directions indicated in the drawings.

Unless otherwise defined, all terms (including technical and scientific terms) used herein have the same meaning as commonly understood by one of ordinary skills in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Further, in this specification, the phrase “on a plane,” or “in a plan view,” means viewing a target portion from the top, and the phrase “on a cross-section” means viewing a cross-section formed by vertically cutting a target portion from the side.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

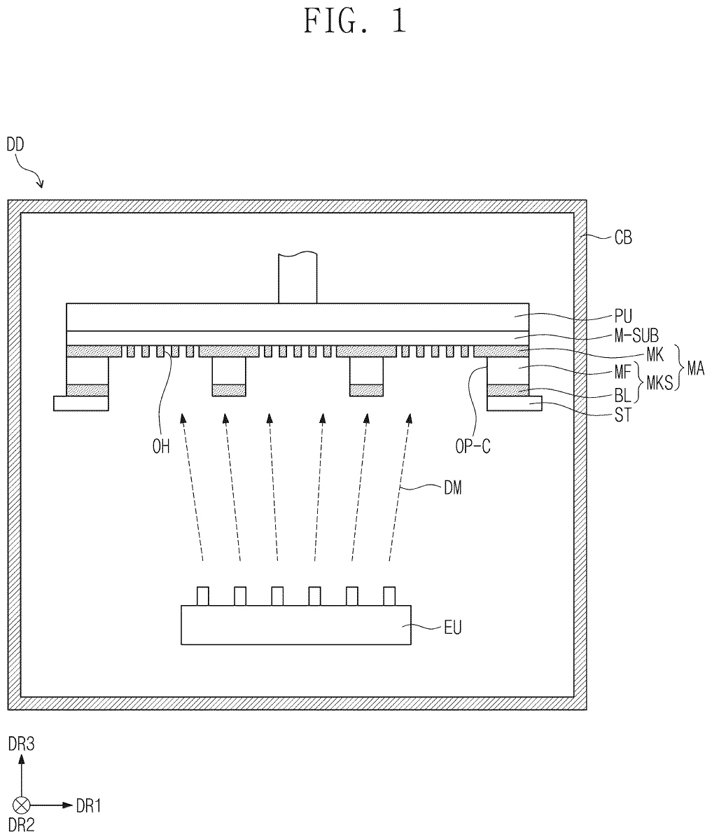

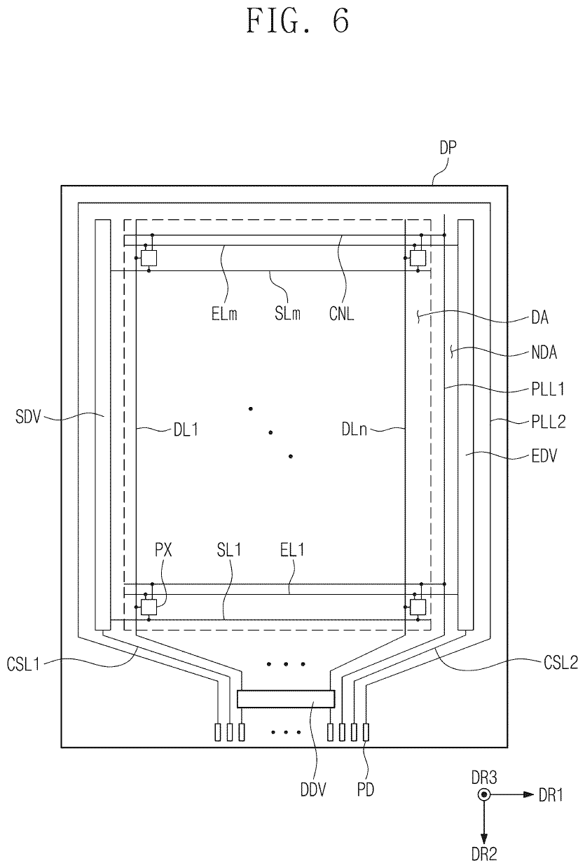

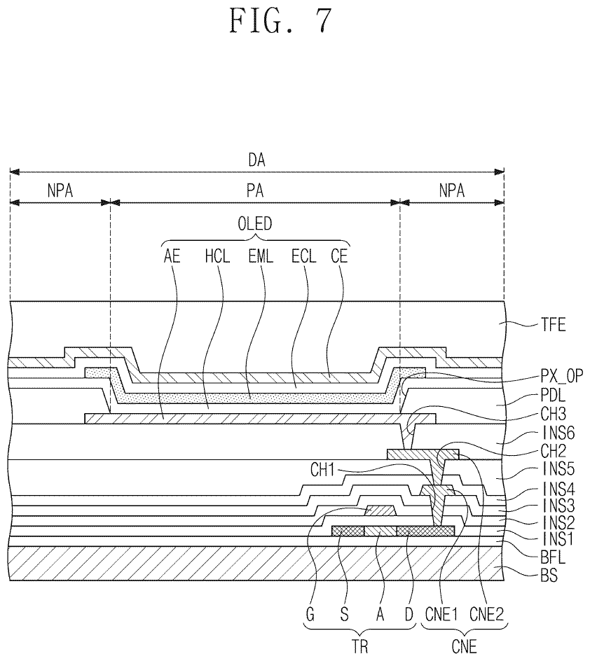

FIG. 1 is a cross-sectional view of a deposition apparatus according to one or more embodiments. A deposition apparatus DD according to one or more embodiments may be used to form at least a part of functional layers included in a display panel DP (see FIG. 6) to be described later. For example, the deposition apparatus DD may be used in a deposition process of a light-emitting layer EML (see FIG. 7) of the display panel DP (see FIG. 6).

Referring to FIG. 1, the deposition apparatus DD may include a chamber CB, a deposition unit EU, a fixing unit PU, a stage ST, and a mask assembly MA. The deposition apparatus DD according to one or more embodiments may further include an additional mechanical device for implementing an in-line system.

The chamber CB may include a floor surface, a ceiling surface, and side walls, which connect the floor surface and the ceiling surface, for providing an internal space. The floor surface of the chamber CB may be parallel to a surface defined by a first direction DR1 and a second direction DR2, and a normal direction of the floor surface of the chamber CB may be parallel to a third direction DR3. In this specification, the wording “on a plane” (e.g., in a plan view) is set based on the surface that is parallel to the surface defined by the first direction DR1 and the second direction DR2.

The deposition unit EU, the fixing unit PU, the stage ST, the mask assembly MA, and a target substrate M-SUB may be disposed in the internal space of the chamber CB. The chamber CB may form a sealed space, and a deposition condition may be set to vacuum. The chamber CB may have at least one gate, and the chamber CB may be opened and closed through the gate. The mask assembly MA and the target substrate M-SUB may enter and exit through the gate provided in the chamber CB.

The fixing unit PU may be disposed above the deposition unit EU inside the chamber CB. The fixing unit PU may fix the mask assembly MA. For example, the fixing unit PU according to one or more embodiments may include a jig or a robot arm for holding the mask assembly MA. The fixing unit PU may include magnetic substances for adhering the mask assembly MA and the target substrate M-SUB. For example, the magnetic substances may generate magnetic force, and apply attractive force to the mask assembly MA. Accordingly, the target substrate M-SUB disposed between the mask assembly MA and the fixing unit PU may be adhered to the mask assembly MA.

The target substrate M-SUB may be an object to be processed on which a deposition material DM is deposited. For example, the target substrate M-SUB may include a support substrate and a synthetic resin layer disposed on the support substrate and corresponding to a base layer BS (see FIG. 7). The support substrate may be removed in a later stage of a manufacturing process of the display panel. Depending on the structure formed through the deposition process, the target substrate M-SUB may include some components of the display panel DP (see FIG. 6) formed on the base layer BS (see FIG. 7).

The deposition unit EU may be disposed facing the fixing unit PU inside the chamber CB. The deposition unit EU may include a space for accommodating the deposition material DM and at least one nozzle for spraying the deposition material DM. The deposition material DM may include a sublimable or evaporable inorganic material, metal, and/or organic material. The deposition material DM may pass through the mask assembly MA and may be deposited on the target substrate M-SUB in a suitable pattern (e.g., a predetermined pattern).

The mask assembly MA may include a mask MK and a mask support part MKS. The mask MK may be disposed on the mask support part MKS to be coupled to the mask support part MKS.

A plurality of holes OH may be defined in the mask MK. A region adjacent to an outer edge of the mask MK may be supported by the mask support part MKS. An upper surface of the mask MK may face an object to be processed. For example, the upper surface of the mask MK may face the target substrate M-SUB.

The plurality of holes OH of the mask MK may overlap a plurality of cell openings OP-C on a plane. The plurality of holes OH may define a region, on the target substrate M-SUB, in which a deposition pattern is formed. That is, the deposition material DM may pass through the plurality of cell openings OP-C and the plurality of holes OH and may be formed, on a deposition surface of the target substrate M-SUB, in a suitable pattern (e.g., a predetermined pattern) corresponding to the plurality of holes OH.

The mask MK may include a silicon-based inorganic material. For example, the mask MK may include silicon oxide (SiOₓ) and/or silicon nitride (SiNₓ). However, the present disclosure is not limited thereto. The mask MK may include a metal material. For example, the mask MK may include an electroformable metal material, such as nickel (Ni), cobalt (Co), titanium (Ti), chrome (Cr), tungsten (W), and/or molybdenum (Mo).

The mask support part MKS may support the mask MK. The plurality of cell openings OP-C may be defined in the mask support part MKS. The plurality of cell openings OP-C may be holes penetrating from an upper surface to a lower surface of the mask support part MKS. A lower surface of the mask MK may be exposed by the plurality of cell openings OP-C. That is, in the deposition apparatus DD, the deposition material may pass through the mask MK via the plurality of cell openings OP-C. The deposition material DM may be deposited on the target substrate M-SUB through the plurality of cell openings OP-C.

The mask support part MKS may include a mask frame MF and a lower layer BL. The mask frame MF may directly support the mask MK. The mask frame MF may include a conductive material. The mask frame MF may include silicon. For example, the mask frame MF may be formed from a silicon wafer, which includes single-crystal silicon. However, the present disclosure is not limited thereto. The mask frame MF may have a suitable rigidity (e.g., a predetermined rigidity). For example, the mask frame MF may include a metal material such as stainless steel (SUS), an invar alloy, nickel (Ni), and/or cobalt (Co).

The lower layer BL may overlap the mask frame MF and may be disposed under the mask frame MF. The lower layer BL and the mask MK may include the same material. Unlike what is illustrated in FIG. 1, the lower layer BL may be integrally formed with the mask MK. The plurality of cell openings OP-C may be formed by passing through the mask frame MF and the lower layer BL.

The stage ST may be disposed between the deposition unit EU and the fixing unit PU to support a frame. The stage ST may be disposed outside a movement path of the deposition material DM which is supplied from the deposition unit EU toward the target substrate M-SUB.

The stage ST may provide a seating surface on which the frame is seated, and the seating surface may be parallel to the first direction DR1 and the second direction DR2. According to one or more embodiments, the seating surface of the stage ST may be provided to be parallel to the floor surface of the chamber CB, and thus be subjected to a horizontal deposition process. However, the present disclosure is not limited thereto, and the seating surface of the stage ST may be provided vertically to the floor surface of the chamber CB, and thus be subjected to a vertical deposition process.

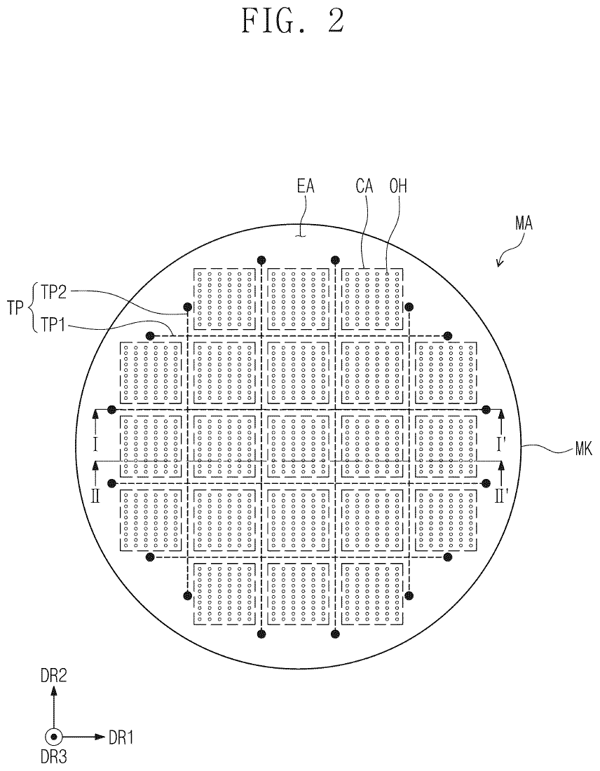

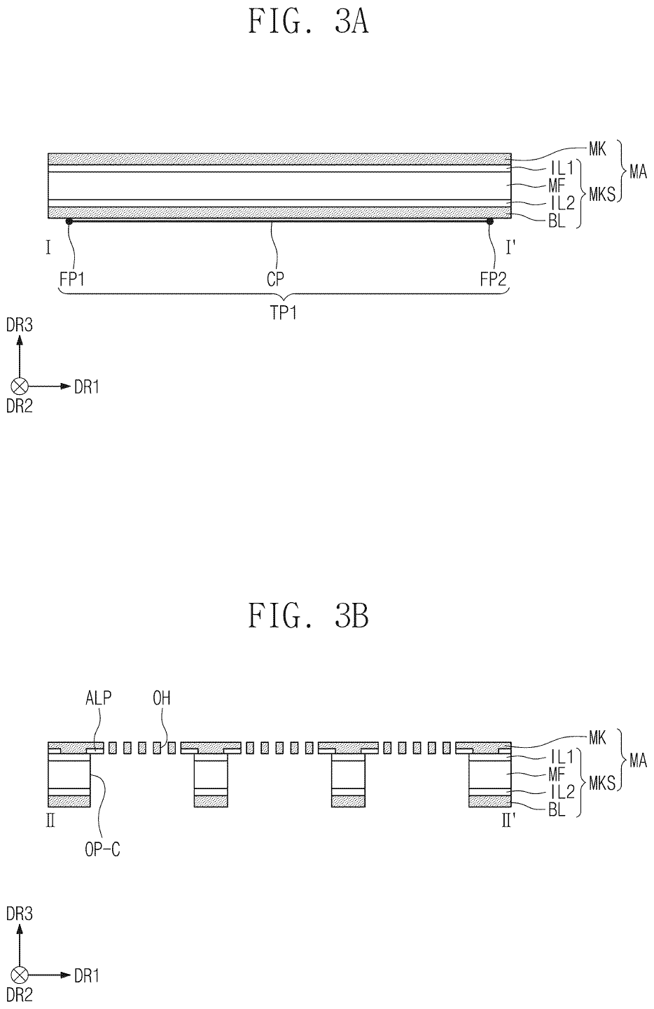

FIG. 2 is a plan view of a mask assembly according to one or more embodiments of the present disclosure. FIG. 3A is a cross-sectional view of a mask assembly taken along the line I-I′ of FIG. 2. FIG. 3B is a cross-sectional view of a mask assembly taken along the line II-II′ of FIG. 2. FIG. 2 is a plan view of a mask assembly when viewed in a third direction DR3. The mask support part MKS (see FIG. 1) disposed under the mask MK is omitted in FIG. 2.

Referring to FIG. 2, a plurality of cell regions CA and a peripheral region EA surrounding the plurality of the cell regions CA may be defined in the mask MK on a plane. The plurality of cell regions CA may be formed corresponding to the plurality of cell openings OP-C (see FIG. 1). A plurality of holes OH penetrating the mask MK along the third direction DR3, which is a thickness direction, may be defined to overlap within the plurality of cell regions CA. The plurality of holes OH may be arranged to be spaced (e.g., spaced apart) from each other in each of the plurality of cell regions CA. As one example of the present disclosure, it is illustrated that the plurality of holes OH are arranged along a first direction DR1 and a second direction DR2, but the present disclosure is not limited thereto. The plurality of holes OH may be defined corresponding to a pattern shape of a light-emitting layer EML (see FIG. 7) of a display panel DP (see FIG. 6).

The mask MK may have a circular shape on a plane. The shape of the mask MK may correspond to a shape of the mask support part MKS (see FIG. 1). An area of the mask MK may be the same as or greater than that of the mask support part MKS. Unlike what is illustrated, the mask MK may have a polygonal shape.

According to one or more embodiments, a mask assembly MA may further include a tension part TP. The tension part TP may be disposed under the mask support part MKS (see FIG. 1). The tension part TP may overlap the peripheral region EA. That is, the tension part TP may not overlap the plurality of cell regions CA. The tension part TP may include a first tension part TP1 and a second tension part TP2. The first tension part TP1 and the second tension part TP2 may each be provided in plurality. The first tension parts TP1 may extend in the first direction DR1 and may be arranged along the second direction DR2. The second tension parts TP2 may extend in the second direction DR2 and may be arranged along the first direction DR1.

Referring to FIGS. 2 and 3A together, the first tension part TP1 may include fixing portions FP1 and FP2 and a connecting portion CP. The fixing portions FP1 and FP2 may include a first fixing portion FP1 corresponding to one side of the first tension part TP1 and a second fixing portion FP2 corresponding to the other side of the first tension part TP1. The connecting portion CP may connect the first fixing portion FP1 and the second fixing portion FP2. The first fixing portion FP1 may be located at a left side of the connecting portion CP, that is, in a direction opposite to the first direction DR1, and the second fixing portion FP2 may be located at a right side of the connecting portion CP, that is, in the first direction DR1. The first fixing portion FP1 and the second fixing portion FP2 may each fix the connecting portion CP to the mask support part MKS.

According to one or more embodiments, the connecting portion CP may include a metal wire. That is, the connecting portion CP may be a metal wire, and formed, for example, by processing metal and/or the like into a linear shape. For example, the connecting portion CP may include steel, aluminum (Al), and/or an alloy thereof. The first fixing portion FP1 and the second fixing portion FP2 may each include a boding material for fixing the connecting portion CP to the mask support part MKS. For example, the first fixing portion FP1 and the second fixing portion FP2 may each include copper (Cu), nickel (Ni), gold (Au), silver (Ag), aluminum (AI), tin (Sn), indium (In), bismuth (Bi), zinc (Zn), antimony (Sb), germanium (Ge), and/or cadmium (Cd). However, the materials for the first fixing portion FP1 and the second fixing portion FP2 are not limited thereto, and thus any material may be used without limitation as long as being easily bondable. In one or more embodiments, the second tension part TP2 may also include fixing portions FP1 and FP2 and a connecting portion CP, and the same description as above may be applied thereto.

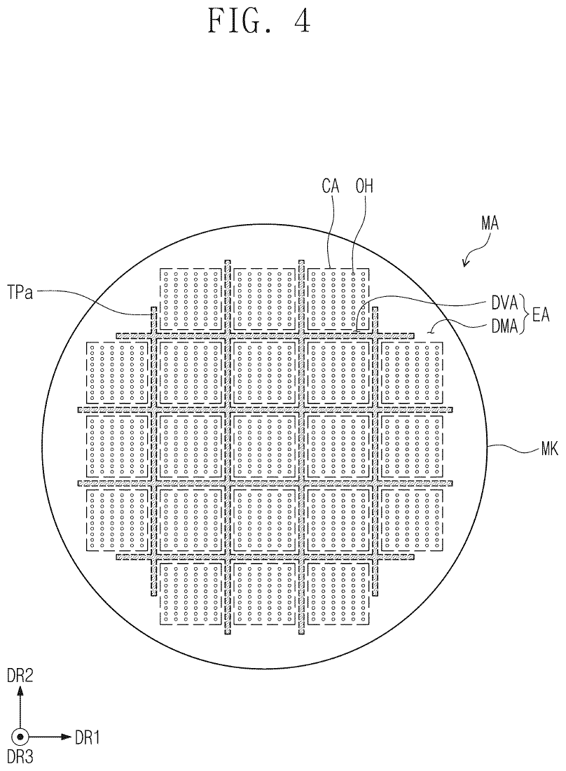

The tension parts TP1 and TP2 may each overlap at least one cell region CA from among the plurality of cell regions CA in the first direction DR1 or in the second direction DR2. For example, the first tension parts TP1 may overlap at least one cell region CA from among the plurality of cell regions CA when viewed in the second direction DR2, and the second tension parts TP2 may overlap at least one cell region CA from among the plurality of cell regions CA when viewed in the first direction DR1. In FIG. 2, it is illustrated that the tension parts TP1 and TP2 extend to the outermost edges of the plurality of cell regions CA, but the present disclosure is not limited thereto. The tension parts TP1 and TP2 may be disposed in a partial region of the peripheral region EA that separates the plurality of cell regions CA. That is, the fixing portions FP1 and FP2 may be disposed in a partial region (for example, a separation region DVA (see FIG. 4)) of the peripheral region EA that separates the plurality of cell regions CA.

The tension parts TP1 and TP2 according to one or more embodiments may provide, to the mask support part MKS, compressive stress which compresses the mask support part MKS (see FIG. 1) together. The fixing portions FP1 and FP2 of the first tension part TP1 may be fixed to the mask support part MKS corresponding thereto, and may provide pulling forces to the mask support part MKS in the first direction DR1 and in the direction opposite to the first direction DR1. Specifically, forces may be provided to pull a portion of the mask support part MKS corresponding to the first fixing portion FP1 in the first direction DR1 and pull a portion of the mask support part MKS corresponding to the second fixing portion FP2 in the direction opposite to the first direction DR1. As a result, the mask MK disposed on the mask support part MKS may be prevented from sagging below the mask support part MKS, and thus the mask MK may be adhered to the target substrate M-SUB (see FIG. 1) during the deposition process of the light-emitting layer EML (see FIG. 7) of the display panel DP (see FIG. 6). Therefore, the display panel DP with reliability may be provided.

Referring to FIG. 3A, the mask support part MKS according to one or more embodiments may further include inorganic layers IL1 and IL2. The inorganic layers IL1 and IL2 may include a first inorganic layer IL1 disposed between a mask frame MF and the mask MK and a second inorganic layer IL2 disposed between the mask frame MF and a lower layer BL. The first inorganic layer IL1 may be disposed between the mask frame MF and the mask MK to adhere the mask frame MF and the mask MK to each other. In addition, the second inorganic layer IL2 may be disposed between the mask frame MF and the lower layer BL to adhere the mask frame MF and the lower layer BL to each other.

The inorganic layers IL1 and IL2 may include an inorganic material having greater adhesive force to each of the mask frame MF, the mask MK, and the lower layer BL, than adhesive force between the mask frame MF and the mask MK, or adhesive force between the mask frame MF and the lower layer BL. For example, the inorganic layers IL1 and IL2 may include a silicon-based inorganic material. The silicon-based inorganic material is not limited to any one material as long as being capable of forming a film through chemical vapor deposition (CVD). Specifically, the inorganic layers IL1 and IL2 may include silicon oxide (SiOₓ) and/or silicon nitride (SiNₓ). FIGS. 3A and 3B illustrate that the first inorganic layer IL1 and the second inorganic layer IL2 are separate layers, but the first inorganic layer IL1 and the second inorganic layer IL2 may be integrally formed.

Referring to FIGS. 2 and 3B, the mask assembly MA according to one or more embodiments may further include an alignment part ALP. The alignment part ALP may be disposed on the mask support part MKS. Specifically, the alignment part ALP may be disposed on the first inorganic layer IL1. The alignment part ALP may be disposed corresponding to the plurality of cell openings OP-C. For example, the alignment part ALP may be disposed corresponding to the peripheral region EA, of the mask MK, which separates the plurality of cell regions CA from each other. The alignment part ALP is a mark for making the plurality of cell openings OP-C be formed to correspond to the plurality of cell regions CA when the plurality of cell openings OP-C are formed. Because the alignment part ALP is formed, the plurality of cell openings OP-C may be formed to correspond to the plurality of cell regions CA.

FIG. 4 is a plan view of a mask assembly according to one or more embodiments of the present disclosure.

Referring to FIG. 4, a peripheral region EA may include a separation region DVA, which separates a plurality of cell regions CA, and a dummy region DMA, which surrounds the separation region DVA. For example, the separation region DVA may be a region disposed between the plurality of cell regions CA, and the dummy region DMA may be a region surrounding the plurality of cell regions CA and the separation region DVA. As illustrated, the separation region DVA and the dummy region DMA may be formed to be connected integrally.

According to one or more embodiments, a tension part TPa may be disposed in the separation region DVA. The tension part TPa may be integrally formed. The tension part TPa may include portions extending in a first direction DR1 and a second direction DR2. The tension part TPa may be provided in a stick shape. The tension part TPa may be disposed under the mask support part MKS (see FIG. 1) and the entire tension part TPa may be fixed to the mask support part MKS. As a result, a mask MK disposed on the mask support part MKS may be prevented from sagging below the mask support part MKS, and thus the mask MK with reliability may be provided.

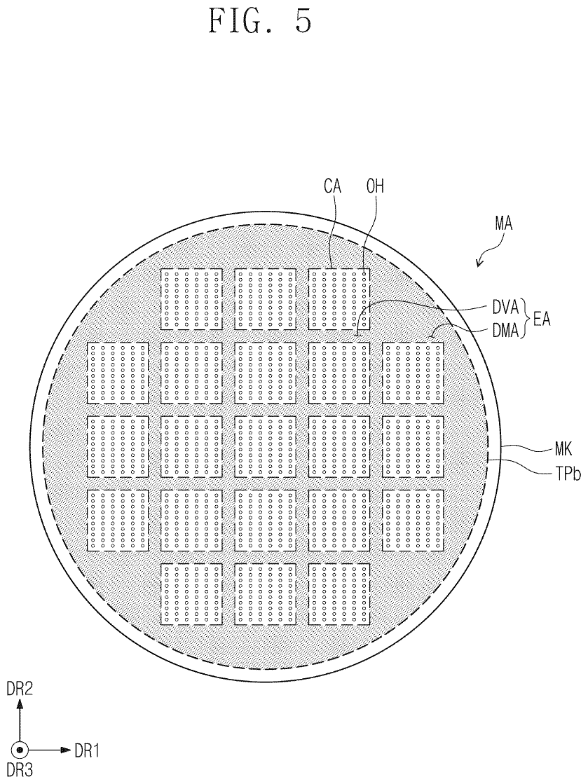

FIG. 5 is a plan view of a mask assembly according to one or more embodiments of the present disclosure.

Referring to FIG. 5, a tension part TPb may be provided in a sheet form. For example, the tension part TPb may overlap a separation region DVA and a portion of a dummy region DMA on a plane. The tension part TPb may not overlap a plurality of cell regions CA. Unlike what is illustrated in FIG. 5, the tension part TPb may overlap the separation region DVA and the entire dummy region DMA on a plane.

FIG. 6 is a plan view of a display panel manufactured using the mask assembly illustrated in FIG. 2.

Referring to FIG. 6, a display panel DP may have a rectangular shape having short sides extending in a first direction DR1 and long sides extending in a second direction DR2, but the shape of the display panel DP is not limited thereto. The display panel DP may include a display region DA and a non-display region NDA around (e.g., surrounding) the display region DA along an edge or a periphery of the display region DA.

The display panel DP may be an emissive display panel. The display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, and/or the like. Hereinafter, the display panel DP will be described as an organic light-emitting display panel.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power supply lines PLL1 and PLL2, connection lines CNL, and a plurality of pads PD. Here, m and n are natural numbers.

The pixels PX may be disposed in the display region DA. A scan driving unit SDV and an emission driving unit EDV may be disposed in the non-display region NDA adjacent to the respective long sides of the display panel DP. A data driving unit DDV may be disposed in the non-display region NDA adjacent to one short side from among the short sides of the display panel DP. When viewed on a plane, the data driving unit DDV may be adjacent to a lower end of the display panel DP.

The scan lines SL1 to SLm may extend in the first direction DR1 to be connected to the pixels PX and the scan driving unit SDV. The data lines DL1 to DLn may extend in the second direction DR2 to be connected to the pixels PX and the data driving unit DDV. The emission lines EL1 to ELm may extend in the first direction DR1 to be connected to the pixels PX and the emission driving unit EDV.

The first power supply line PLL1 may extend in the second direction DR2 and may be disposed in the non-display region NDA. The first power supply line PLL1 may be disposed between the display region DA and the emission driving unit EDV, but the present disclosure is not limited thereto, and may be disposed between the display region DA and the scan driving unit SDV.

The connection lines CNL may extend in the first direction DR1 and may be arranged along the second direction DR2. The connection lines CNL may be connected to the first power supply line PLL1 and the pixels PX. A first voltage may be applied to the pixels PX through the first power supply line PLL1 and the connection lines CNL, which are connected to each other.

The second power supply line PLL2 may be disposed in the non-display region NDA. The second power supply line PLL2 may extend along the long sides of the display panel DP and the other short side, of the display panel DP, in which the data driving unit DDV is not disposed. The second power supply line PLL2 may be disposed outside the scan driving unit SDV and the emission driving unit EDV.

In one or more embodiments, the second power supply line PLL2 may extend toward the display region DA to be connected to the pixels PX. A second voltage, which has a lower voltage level than the first voltage, may be applied to the pixels PX through the second power supply line PLL2.

The first control line CSL1 may be connected to the scan driving unit SDV, and may extend toward the lower end of the display panel DP when viewed on a plane. The second control line CSL2 may be connected to the emission driving unit EDV, and may extend toward the lower end of the display panel DP when viewed on a plane. The data driving unit DDV may be disposed between the first control line CSL1 and the second control line CSL2.

The pads PD may be disposed on the display panel DP. The pads PD may be more adjacent to the lower end of the display panel DP than the data driving unit DDV. The data driving unit DDV, the first power supply line PLL1, the second power supply line PLL2, the first control line CSL1, and the second control line CSL2 may be connected to the pads PD. The data lines DL1 to DLn may be connected to the data driving unit DDV, and the data driving unit DDV may be connected to the pads PD corresponding to the data lines DL1 to DLn.

Light-emitting elements of the display panel DP may be formed by the plurality of cell regions CA illustrated in FIG. 2. In a target substrate M-SUB, unit regions corresponding to the display panel DP may be defined. The light-emitting elements may be formed in the unit regions, and then the unit regions may be cut off. As a result, the display panel DP illustrated in FIG. 6 may be manufactured.

In one or more embodiments, a timing controller for controlling operations of the scan driving unit SDV, the data driving unit DDV, and the emission driving unit EDV, and a voltage generator for generating the first and second voltages may be disposed on a printed circuit board (PCB). The timing controller and the voltage generator may be connected to the corresponding pads PD through the printed circuit board (PCB).

The scan driving unit SDV may generate a plurality of scan signals, and the scan signals may be applied to the pixels PX through the scan lines SL1 to SLm. The data driving unit DDV may generate a plurality of data voltages, and the data voltages may be applied to the pixels PX through the data lines DL1 to DLn. The emission driving unit EDV may generate a plurality of light-emitting signals, and the light-emitting signals may be applied to the pixels PX through the emission lines EL1 to ELm.

The pixels PX may receive the data voltages in response to the scan signals. The pixels PX may display an image by emitting light with luminance corresponding to the data voltages in response to the light-emitting signals. The emission time of the pixels PX may be controlled by the light-emitting signals.

The aforementioned lines may include the data lines DL1 to DLn. Pads connected to the aforementioned lines may include the pads PD illustrated in FIG. 6. The display panel DP in which light-emitting layers of the pixels PX are not formed may be defined as the aforementioned target substrate M-SUB.

A cross-sectional structure of the target substrate M-SUB (see FIG. 1), in which the light-emitting layers are formed, will be described with reference to FIG. 7. The pads PD may be formed on the target substrate M-SUB, and the target substrate M-SUB may be defined as being in a state in which the printed circuit board (PCB) is not connected. The pads PD may be connected to a ground terminal GND, and the pads PD and the data lines DL1 to DLn may be grounded.

FIG. 7 illustrates an example cross sectional view of one pixel illustrated in FIG. 6.

Referring to FIGS. 6 and 7 together, a pixel PX may be disposed on a base substrate BS, and may include a transistor TR and a light-emitting element OLED. The transistors TR and the light-emitting elements OLED of the pixels PX may be connected to the data lines DL1 to DLn and the first and second power supply lines PLL1 and PLL2, which have been mentioned above. The transistors TR and the light-emitting elements OLED of the pixels PX may be connected to the pads PD through the data lines DL1 to DLn and the first and second power supply lines PLL1 and PLL2.

The light-emitting element OLED may include a first electrode AE, a second electrode CE, a hole control layer HCL, an electron control layer ECL, and a light-emitting layer EML. The first electrode AE may be an anode, and the second electrode CE may be a cathode.

The transistor TR and the light-emitting element OLED may be disposed on the base substrate BS. One transistor TR is illustrated as an example, but substantially, the pixel PX may include at least one capacitor and a plurality of transistors so as to drive the light-emitting element OLED.

A display region DA may include an emission region PA corresponding to the pixels PX and a non-emission region NPA around the emission region PA. The light-emitting element OLED may be disposed in the emission region PA.

The base substrate BS may include a flexible plastic substrate. For example, the base substrate BS may include a transparent polyimide (PI). A buffer layer BFL may be disposed on the base substrate BS, and the buffer layer BFL may be an inorganic layer.

A semiconductor pattern may be disposed on the buffer layer BFL. The semiconductor pattern may include polysilicon. However, the present disclosure is not limited thereto, and the semiconductor pattern may include amorphous silicon or metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may substantially serve as a source electrode and a drain electrode of the transistor TR. The lightly doped region may substantially correspond to an active (or channel) region of the transistor.

A source S, an active region A, and a drain D of the transistor TR may be formed from the semiconductor pattern. A first insulation layer INS1 may be disposed on the buffer layer to cover the semiconductor pattern. A gate G of the transistor TR may be disposed on the first insulation layer INS1. A second insulation layer INS2 may be disposed on the first insulation layer INS1 to cover the gate G. A third insulation layer INS3 may be disposed on the second insulation layer INS2.

A connection electrode CNE may be disposed between the transistor TR and the light-emitting element OLED to connect the transistor TR and the light-emitting element OLED. The connection electrode CNE may include a first connection electrode CNE1 and a second connection electrode CNE2.

The first connection electrode CNE1 may be disposed on the third insulation layer INS3, and connected to the drain D through a first contact hole CH1 that is defined in the first to third insulation layers INS1 to INS3. A fourth insulation layer INS4 may be disposed on the third insulation layer INS3 to cover the first connection electrode CNE1. A fifth insulation layer INS5 may be disposed on the fourth insulation layer INS4.

The second connection electrode CNE2 may be disposed on the fifth insulation layer INS5. The second connection electrode CNE2 may be connected to the first connection electrode CNE1 through a second contact hole CH2 that is defined in the fourth insulating layer INS4 and the fifth insulation layer INS5. A sixth insulation layer INS6 may be disposed on the fifth insulation layer INS5 to cover the second connection electrode CNE2. The first to sixth insulation layers INS1 to INS6 may be inorganic layers and/or organic layers.

The first electrode AE may be disposed on the sixth insulation layer INS6. The first electrode AE may be connected to the second connection electrode CNE2 through a third contact hole CH3 that is defined in the sixth insulation layer INS6. A pixel-defining film PDL exposing a suitable portion (e.g., a predetermined portion) of the first electrode AE may be disposed on the first electrode AE and the sixth insulation layer INS6. An opening PX_OP for exposing the suitable portion (e.g., the predetermined portion) of the first electrode AE may be defined in the pixel-defining film PDL.

The hole control layer HCL may be disposed on the first electrode AE and the pixel-defining film PDL. The hole control layer HCL may be disposed in the emission region PA and the non-emission region NPA in common. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate one light from among red, green, and blue light.

The electron control layer ECL may be disposed on the light-emitting layer EML and the hole control layer HCL. The electron control layer ECL may be disposed in the emission region PA and the non-emission region NPA in common. The electron control layer ECL may include an electron transport layer and an electron injection layer.

The second electrode CE may be disposed on the electron control layer ECL. The second electrode CE may be disposed in the pixels PX in common. Layers from the buffer layer BFL to the light-emitting element OLED may be defined as a pixel layer PXL.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers and an organic layer between the inorganic layers. The inorganic layer may protect the pixel PX from moisture and/or oxygen. The organic layer may protect the pixel PX from foreign matters such as dust particles.

A first voltage may be applied to the first electrode AE through the transistor TR, and a second voltage having a lower voltage level than the first voltage may be applied to the second electrode CE. The holes and the electrons injected into the light-emitting layer EML combine to form excitons, and when the excitons transition to a ground state, the light-emitting element OLED may emit light.

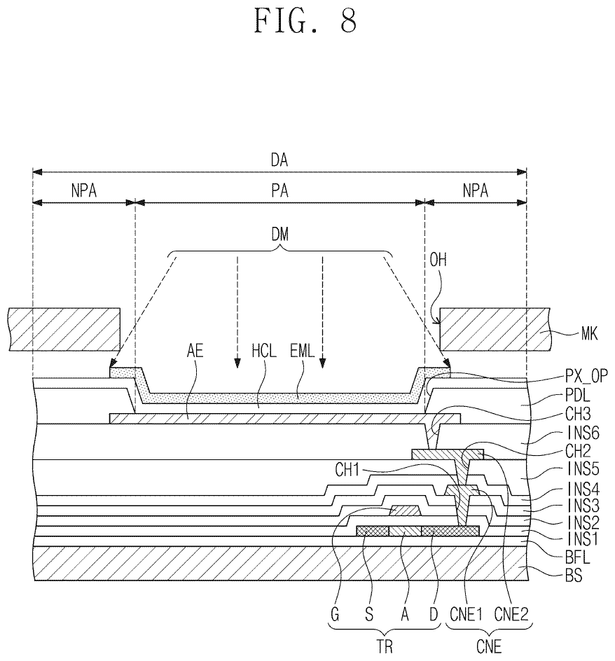

FIG. 8 illustrates a deposition process illustrated in FIG. 1.

Referring to FIGS. 1, 6, and 8 together, a structure from a base substrate BS up to a layer on which a first electrode AE is disposed may be defined as a target substrate M-SUB. As mentioned above, a transistor TR may be connected to pads PD through data lines DL1 to DLn. That is, the target substrate M-SUB may include the data lines DL1 to DLn, which are defined as the aforementioned lines and the pads PD connected to the data lines DL1 to DLn.

A mask MK may be disposed to face the target substrate M-SUB. The mask MK may be disposed to be close to the target substrate M-SUB. A deposition material DM may be supplied onto the target substrate M-SUB through a plurality of holes OH defined in the mask MK. A light-emitting layer EML may be formed on the target substrate M-SUB by the deposition material DM.

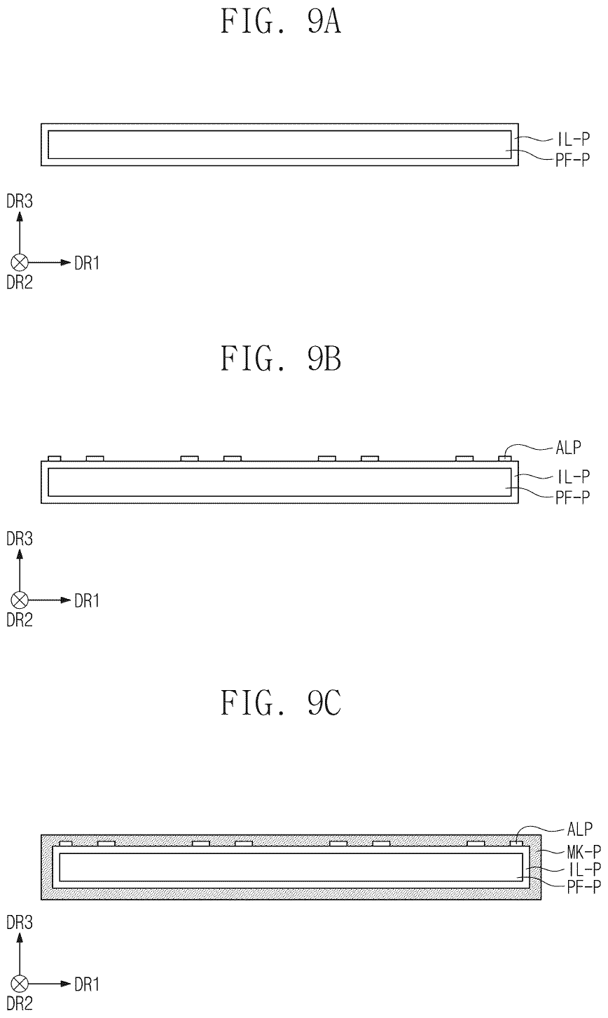

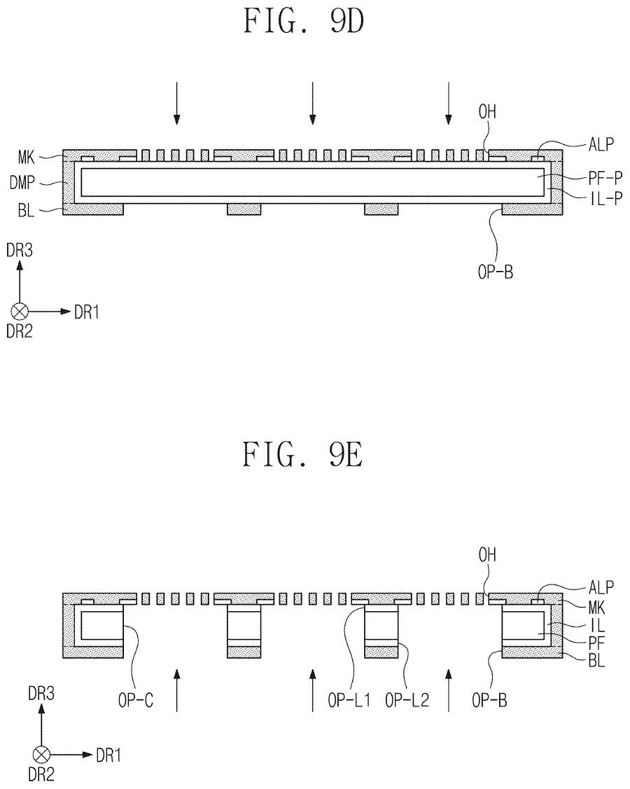

FIGS. 9A-9E are cross-sectional views illustrating some steps of a method of manufacturing a mask assembly according to one or more embodiments.

Referring to FIG. 9A, a step of forming a preliminary mask frame PF-P and a step of forming a preliminary inorganic layer IL-P may be performed.

The preliminary mask frame PF-P may have a rectangular shape on a cross section. The preliminary mask frame PF-P may include a conductive material. The preliminary mask frame PF-P may include silicon. For example, the preliminary mask frame PF-P may be formed from a silicon wafer, which includes single-crystal silicon. However, the present disclosure is not limited thereto. The preliminary mask frame PF-P may have a suitable rigidity (e.g., a predetermined rigidity). For example, the preliminary mask frame PF-P may include a metal material such as stainless steel (SUS), an invar alloy, nickel (Ni), and/or cobalt (Co). In one or more embodiments, the preliminary mask frame PF-P may have a circular shape when viewed in a third direction DR3.

The preliminary inorganic layer IL-P may cover the preliminary mask frame PF-P. That is, the preliminary inorganic layer IL-P may be integrally formed while being around (e.g., surrounding) the preliminary mask frame PF-P. The preliminary inorganic layer IL-P may include a silicon-based inorganic material. The silicon-based inorganic material is not limited to any one material as long as being capable of forming a film through chemical vapor deposition (CVD). Specifically, the preliminary inorganic layer IL-P may include silicon oxide (SiOₓ) and/or silicon nitride (SiNₓ).

Referring to FIG. 9B, an alignment part ALP may be formed on the preliminary inorganic layer IL-P. The alignment part ALP may be disposed corresponding to a plurality of cell openings OP-C (see FIG. 9E). The alignment part ALP is a mark for making the plurality of cell openings OP-C be formed to correspond to the plurality of cell regions CA (see FIG. 2) when the plurality of cell openings OP-C are formed. Because the alignment part ALP is formed, the plurality of cell openings OP-C may be formed to correspond to the plurality of cell regions CA.

Referring to FIG. 9C, a preliminary mask MK-P may be formed on the preliminary inorganic layer IL-P. The preliminary mask MK-P may cover the preliminary inorganic layer IL-P. That is, the preliminary mask MK-P may be integrally formed while being around (e.g., surrounding) the preliminary inorganic layer IL-P. The preliminary mask MK-P may include a silicon-based inorganic material.

For example, the preliminary mask MK-P may include silicon oxide (SiOₓ) and/or silicon nitride (SiNₓ). The preliminary mask MK-P may be adhered to the preliminary inorganic layer IL-P.

Referring to FIGS. 9C and 9D together, a step of forming a mask MK, a lower layer BL, and a dummy part DMP connecting the mask MK and the lower layer BL by performing a first etching of etching the preliminary mask MK-P may be performed. Specifically, an upper surface of the preliminary mask MK-P may be etched to form a plurality of holes OH in the mask MK. In addition, at the same time, a lower surface of the preliminary mask MK-P may be etched to form, in the lower layer BL, a plurality of lower openings OP-B corresponding to the plurality of cell openings OP-C (see FIG. 9E) to be described later. The first etching may be performed through dry etching.

The dummy part DMP may be omitted in one or more embodiments. The mask MK and the lower layer BL may be respectively the same as the mask MK and the lower layer BL illustrated in FIG. 1.

Referring to FIGS. 9D and 9E together, a step of forming a mask frame PF and an inorganic layer IL by performing a second etching of etching the preliminary mask frame PF-P and the preliminary inorganic layer IL-P may be performed. Specifically, lower parts of the preliminary mask frame PF-P and the preliminary inorganic layer IL-P may be etched to respectively form the plurality of cell openings OP-C in the mask frame PF and a plurality of inorganic openings OP-L1 and OP-L2 in the inorganic layer IL.

The plurality of lower openings OP-B, the plurality of cell openings OP-C, and the plurality of inorganic openings OP-L1 and OP-L2 may be formed in parallel to a third direction DR3. However, the present disclosure is not limited thereto, and the plurality of lower openings OP-B, the plurality of cell openings OP-C, and the plurality of inorganic openings OP-L1 and OP-L2 may be formed to have different widths depending on respective etch rates of the lower layer BL, the mask frame PF, and the inorganic layer IL.

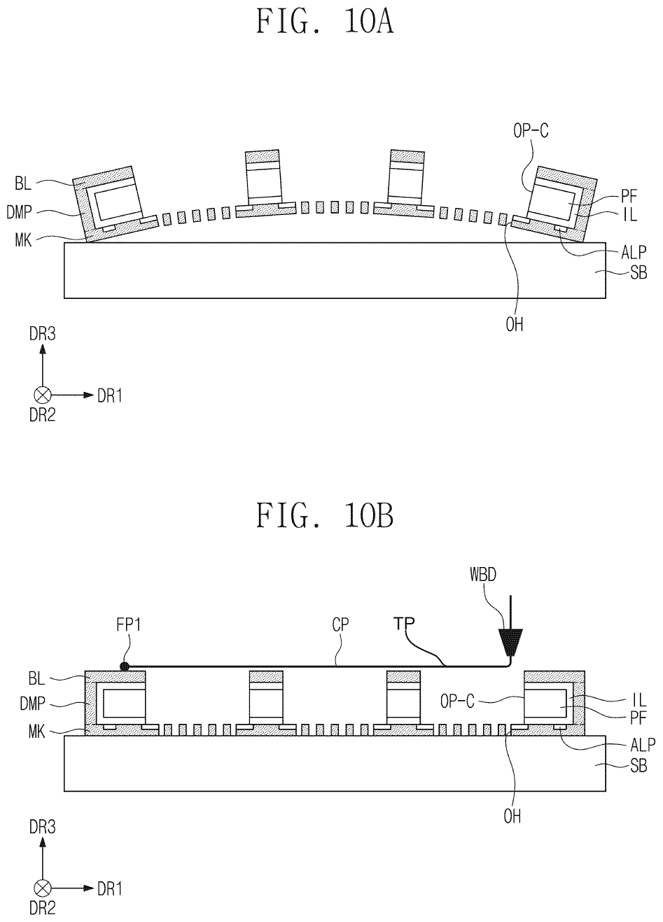

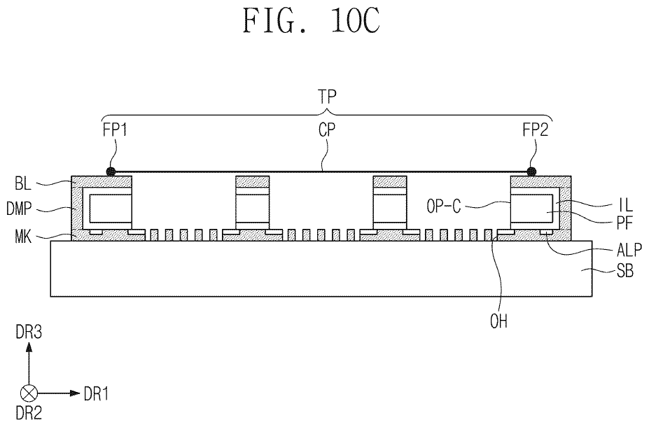

FIGS. 10A-10C are cross-sectional views illustrating some steps of a method of manufacturing a mask assembly according to one or more embodiments.

Referring to FIG. 10A, a step of turning a lower layer BL, a mask frame PF, an inorganic layer IL, and a mask MK upside down may be performed. In one or more embodiments, during the process of forming the mask MK illustrated in FIG. 9E, a phenomenon in which the mask MK disposed on the inorganic layer IL sags in a direction opposite to a third direction DR3 due to the load of the mask MK may occur. A step of turning the mask MK upside down and disposing the mask MK, which is curved in the third direction DR3, on a substrate SB may be performed.

Referring to FIGS. 10B and 10C together, a step of fixing a tension part TP to the lower layer BL may be performed. Specifically, a first fixing step of fixing a first fixing portion FP1 to one portion (for example, a first portion) of the lower layer BL and a second fixing step of fixing a second fixing portion FP2 to another portion (for example, a second portion) of the lower layer BL may be performed.

The tension part TP may be fixed to the first portion of the lower layer BL through a bonder WBD, and then fixed to the second portion of the lower layer BL by pulling the second portion of the lower layer BL in a direction opposite to a first direction DR1. The first fixing portion FP1 and the second fixing portion FP2 may include a bonding material. For example, the first fixing portion FP1 and the second fixing portion FP2 may each include copper (Cu), nickel (Ni), gold (Au), silver (Ag), aluminum (Al), tin (Sn), indium (In), bismuth (Bi), zinc (Zn), antimony (Sb), germanium (Ge), and/or cadmium (Cd). The bonding material may be provided to the first portion and the second portion of the lower layer BL, and the tension part TP may be fixed to the first portion and the second portion of the lower layer BL through thermal treatment.

Unlike what is illustrated in FIGS. 10A-10C, the tension part TP may not overlap a plurality of holes OH of the mask MK. Specifically, the tension part TP may be disposed in a peripheral region EA as illustrated in FIG. 3. That is, the tension part TP may not overlap a plurality of cell regions CA. However, in FIGS. 10A-10C, it is merely illustrated for convenience of explanation that the tension part TP seems to overlap the plurality of cell regions CA.

Through the first fixing step and the second fixing step of the tension part TP, the first portion and the second portion of the lower layer BL may become close to each other in the first direction DR1. As a result, the mask MK, which sags in the direction opposite to the third direction DR3 due to the load, may be stretched in the first direction DR1 and prevented from sagging in the direction opposite to the third direction DR3, and therefore the mask MK with reliability may be provided.

A mask assembly according to the present disclosure may include a mask support part, a mask disposed on the mask support part, and a tension part disposed under the mask support part. One side of the tension part may be fixed to a first portion of the mask support part, and the other side of the tension part may be fixed to a second portion of the mask support part, and thus compressive stress may be provided to the first portion of the mask support part and the second portion of the mask support part. As a result, the mask disposed on the mask support part may be prevented from sagging below the mask support part by receiving tensile stress, and therefore the mask with reliability may be provided.

In the above, description has been made with reference to one or more embodiments, but those skilled in the art or those of ordinary skill in the relevant technical field may understand that various modifications and changes may be made to the present disclosure within the scope not departing from the spirit and the technology scope of the present disclosure described in the claims to be described later.

Therefore, the technical scope of the present disclosure is not limited to the contents described in the detailed description of the specification, but may be determined by the claims and their equivalents.

What is claimed is:

1. A mask assembly comprising:
a mask support part having a plurality of cell openings;
a mask on the mask support part, and including a plurality of cell regions overlapping the plurality of cell openings and a peripheral region surrounding the plurality of cell regions; and
a tension part under the mask support part and overlapping the peripheral region,
wherein one side of the tension part and an other side of the tension part, which is opposite to the one side of the tension part, are fixed to the mask support part.

2. The mask assembly of claim 1, wherein the tension part comprises:
a first fixing portion corresponding to the one side;
a second fixing portion corresponding to the other side; and
a connecting portion configured to connect the first fixing portion and the second fixing portion.

3. The mask assembly of claim 2, wherein the connecting portion extends in a first direction, and overlaps at least one cell region from among the plurality of cell regions in a second direction perpendicular to the first direction on a plane.

4. The mask assembly of claim 1, wherein the tension part comprises:
a first tension part extending in a first direction; and
a second tension part extending in a second direction perpendicular to the first direction.

5. The mask assembly of claim 4, wherein the first tension part comprises a plurality of first tension parts and the second tension part comprises a plurality of second tension parts.

6. The mask assembly of claim 1, wherein the peripheral region comprises:
a separation region separating the plurality of cell regions; and
a dummy region surrounding the separation region.

7. The mask assembly of claim 6, wherein the tension part overlaps the separation region, and does not overlap the dummy region, and
wherein the tension part is fixed to the mask support part in the separation region.

8. The mask assembly of claim 6, wherein the tension part overlaps the separation region and the dummy region, and
wherein the tension part is fixed to the mask support part in the separation region and the dummy region.

9. The mask assembly of claim 1, wherein the mask support part comprises a mask frame and a lower layer under the mask frame, and
wherein the lower layer and the mask comprise a same material.

10. The mask assembly of claim 9, wherein the mask frame comprises a silicon wafer.

11. The mask assembly of claim 9, wherein the mask support part further comprises:
a first inorganic layer between the mask frame and the mask; and
a second inorganic layer between the mask frame and the lower layer.

12. The mask assembly of claim 1, further comprising an alignment part on the mask support part.

13. The mask assembly of claim 1, wherein each of the mask support part and the mask have a circular shape on a plane.

14. A method of manufacturing a mask assembly, the method comprising:
forming a preliminary mask frame having conductivity;
forming a preliminary mask on the preliminary mask frame;
forming a mask by forming a plurality of holes passing through the preliminary mask;
forming a mask frame by forming a plurality of cell openings in the preliminary mask frame; and
fixing, to the mask frame, a tension part which does not overlap the plurality of cell openings on a plane.

15. The method of claim 14, wherein the fixing of the tension part to the mask frame comprises:
performing a first fixing to fix one side of the tension part to a first portion of the mask frame; and
performing a second fixing to fix an other side of the tension part, which is opposite to the one side of the tension part, to a second portion of the mask frame, the second portion of the mask frame being spaced from the first portion of the mask frame in a first direction.

16. The method of claim 15, wherein through the first fixing and the second fixing, the first portion and the second portion come to close to each other in the first direction.

17. The method of claim 15, wherein through the first fixing and the second fixing, the mask is stretched in the first direction.

18. The method of claim 14, further comprising forming an alignment part on the preliminary mask frame before the forming of the preliminary mask.

19. The method of claim 14, further comprising turning the mask and the mask frame upside down before the fixing of the tension part to the mask frame.

20. The method of claim 14, wherein each of the mask frame and the mask has a circular shape on a plane.
